(19) United States
(12) Patent Application Publication
(10) Pub. No.: US 2014/0144505 A1
(43) Pub. Date: May 29, 2014

(54) GLASS USED IN OPTICAL ELEMENT FOR CONCENTRATING PHOTOVOLTAIC POWER GENERATION APPARATUS, OPTICAL ELEMENT FOR CONCENTRATING PHOTOVOLTAIC POWER GENERATION APPARATUS USING GLASS, AND CONCENTRATING PHOTOVOLTAIC POWER GENERATION APPARATUS

(71) Applicants: Takahiro Matano, Otsu-shi (JP); Fumio Sato, Otsu-shi (JP)

(72) Inventors: Takahiro Matano, Otsu-shi (JP); Fumio Sato, Otsu-shi (JP)

(73) Assignee: NIPPON ELECTRIC GLASS CO., LTD., Otsu-shi, Shiga (JP)

(21) Appl. No.: 14/131,209

(22) PCT Filed: Jun. 21, 2012
(86) PCT No.: PCT/JP2012/065840

§ 371 Date: Jan. 7, 2014

(30) Foreign Application Priority Data
Jul. 26, 2011 (JP) 2011-162951
Sep. 9, 2011 (JP) 2011-196671

(51) Int. Cl. H01L 31/052; C03C 3/089; C03C 3/068; C03C 3/093; C03C 3/085; C03C 3/087; C03C 3/097; C03C 3/091

(52) U.S. Cl. CPC H01L 31/0525; C03C 3/097; C03C 3/089; C03C 3/091; C03C 3/093; C03C 3/085; C03C 3/087; C03C 3/068
USPC 136/259; 252/582

(57) ABSTRACT

Provided are a glass which is used in an optical element for a concentrating photovoltaic power generation apparatus, has excellent weather resistance, and can be easily processed into a complicated shape; an optical element for a concentrating photovoltaic power generation apparatus using the glass; and a concentrating photovoltaic power generation apparatus. The glass used in an optical element for a concentrating photovoltaic power generation apparatus contains, in % by mass, 30 to 80% SiO₂, 0 to 40% B₂O₃, 0 to 20% Al₂O₃, not less than 0.1% Li₂O, and not less than 0.1% ZrO₂.

### TECHNICAL FIELD

This invention relates to a glass used in an optical element for a concentrating photovoltaic power generation apparatus, an optical element for a concentrating photovoltaic power generation apparatus using the glass, and a concentrating photovoltaic power generation apparatus.

### BACKGROUND ART

In a conventional concentrating photovoltaic power generation apparatus, an optical element made of glass is provided between a collecting lens and a solar cell. The optical element totally reflects light collected by the collecting lens on the inner surface thereof and transmits the light to the solar cell. Examples of the material used for the optical element include borosilicate glass as disclosed in Patent Literature 1 and silicate glass as disclosed in Patent Literature 2. The optical element generally has a trapezoidal pyramid, a conical or a similar shape and can be made by grinding and polishing an ingot of glass material.

Because concentrating photovoltaic power generation apparatuses are mainly used outdoors, optical elements used therein are required to have excellent weather resistance. For example, Patent Literature 3 proposes a method in which a thin fluororesin film is provided on the side surface of the optical element. With this method, it is possible to prevent portions of the surface of the optical element from being made cloudy such as with water drops and thus causing leakage of part of light there through.

### CITATION LIST

### Patent Literature

Patent Literature 1: JP-A-2006-313809
Patent Literature 2: JP-A-2010-199588
Patent Literature 3: JP-A-2006-278581

### SUMMARY OF INVENTION

### Technical Problem

Conventional glass-made optical elements used in concentrating photovoltaic power generation apparatuses have insufficient weather resistance so that they are likely to cause failures, such as surface alteration, when used outdoors for long periods. Therefore, there is a need to further improve the weather resistance of the optical element.

Meanwhile, with a view to further increasing the power generation efficiency of the concentrating photovoltaic power generation apparatus and further reducing the size thereof, it is anticipated that the optical element will be required to have a more complicated shape, such as a shape having a curved end surface or a polygonal pyramid shape. However, such a complicated shape is difficult to achieve by grinding and polishing and these methods have a disadvantage in terms of cost.

With the foregoing in mind, an object of the present invention is to provide: a glass which is used in an optical element for a concentrating photovoltaic power generation apparatus, has excellent weather resistance, and can be easily processed into a complicated shape; an optical element for a concentrating photovoltaic power generation apparatus using the glass; and a concentrating photovoltaic power generation apparatus.

### Solution to Problem

An aspect of the present invention relates to a glass used in an optical element for a concentrating photovoltaic power generation apparatus, the glass containing, in % by mass, 30 to 80% SiO₂, 0 to 40% B₂O₃, 0 to 20% Al₂O₂, not less than 0.1% Li₂O, and not less than 0.1% ZrO₂.

An optical element made of the glass having the above composition has excellent weather resistance so that it is less likely to cause failures, such as surface alteration, even when used outdoors for long periods. In addition, the glass is capable of easily achieving a low softening point or a low viscosity, which is suitable for melting and molding. Therefore, by appropriately selecting the shape of a mold, an optical element having a complicated shape can be easily produced.

In a second aspect of the present invention, the glass preferably further contains, in % by mass, 0 to 20% CaO, 0 to 20% SrO, 0 to 20% BaO, 0 to 20% MgO, 0 to 20% ZnO, 0 to 20% Na₂O, 0 to 20% K₂O, and 0 to 10% TiO₂.

In a third aspect of the present invention, the glass preferably further contains, in % by mass, 0 to 20% Bi₂O₂+La₂O₂+Gd₂O₅+Ta₂O₅+TiO₂+Nb₂O₅+WO₂.

In a fourth aspect of the present invention, the glass preferably further contains, in % by mass, 0 to 5% CeO₂+Pr₂O₂+Nd₂O₂+Eu₂O₂+Tb₂O₂+Er₂O₂+Y₂O₂+Yb₂O₅.

In a fifth aspect of the present invention, the glass preferably has a Fe₂O₃ content of not more than 500 ppm.

In a sixth aspect of the present invention, the glass is preferably substantially free of lead component, arsenic component, and fluorine component.

With this composition, an environmentally friendly glass can be provided. As used herein, “substantially free of lead component, arsenic component, and fluorine component” means that no amount of these components are deliberately incorporated into the glass and does not mean to exclude even the unavoidable incorporation of impurities. Specifically, this means that the content of each of these components is below 0.1%.

In a seventh aspect of the present invention, the glass preferably has an average linear coefficient of thermal expansion of 120×10⁻⁷/° C. or less at 30 to 300° C.

With this composition, breakage of the glass due to temperature changes during cooling after molding or during outdoor use can be reduced.

In an eighth aspect of the present invention, the temperature of the glass corresponding to a viscosity of 10^{2.0} Pa·s is preferably 1300° C. or less.

With this composition, the glass can be improved in meltability and moldability.

In a ninth aspect of the present invention, the glass preferably has a softening point of 750° C. or less.

With this composition, the degradation of the mold during molding can be reduced.

In a tenth aspect of the present invention, the glass with a thickness of 10 mm preferably has an internal transmittance of not less than 90% at a wavelength of 400 nm.

With the use of an optical element made of the glass satisfying this composition, the power generation efficiency of a resultant concentrating photovoltaic power generation apparatus can be increased.

In an eleventh aspect of the present invention, the glass with a thickness of 10 mm preferably has an internal transmittance of not more than 40% at a wavelength of 300 nm.

A twelfth aspect of the present invention relates to an optical element for a concentrating photovoltaic power generation apparatus, the optical element being made of the glass according to any one of the foregoing aspects.

A thirteenth aspect of the present invention relates to a concentrating photovoltaic power generation apparatus including a solar cell and a collecting optical system configured to collect light to the solar cell, the collecting optical system including the optical element according to any one of the above aspects.

### BRIEF DESCRIPTION OF DRAWINGS

FIG. 1 is a schematic conceptual view of a concentrating photovoltaic power generation apparatus according to one embodiment of the present invention.

FIG. 2 is a schematic perspective view of an optical element according to the one embodiment of the present invention.

### DESCRIPTION OF EMBODIMENTS

Hereinafter, a description will be given of an exemplary preferred embodiment for working of the present invention. However, the following embodiment is simply illustrative. The present invention is not at all limited to the following embodiment.

Throughout the drawings to which the embodiment and the like refer, elements having substantially the same functions will be referred to by the same reference signs. The drawings to which the embodiment and the like refer are schematically illustrated, and the dimensional ratios and the like of objects illustrated in the drawings may be different from those of the actual objects. Different drawings may have different dimensional ratios and the like of the objects. Dimensional ratios and the like of specific objects should be determined in consideration of the following descriptions.

(Concentrating Photovoltaic Power Generation Apparatus)

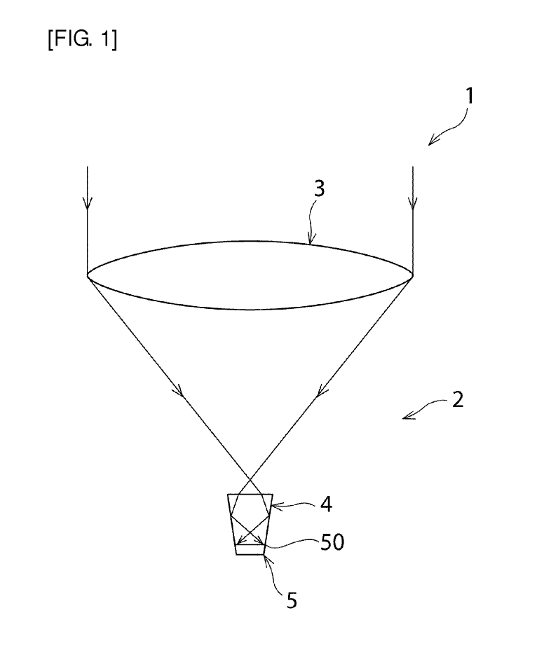

FIG. 1 is a schematic conceptual view of a concentrating photovoltaic power generation apparatus with an optical element according to this embodiment.

The concentrating photovoltaic power generation apparatus 1 includes a solar cell 5 and a collecting optical system 2 configured to collect sunlight to the solar cell 5. The collecting optical system 2 includes a light collecting member 3 and an optical element 4. The light collecting member 3 collects light, such as sunlight. The light collecting member 3 can be formed of, for example, a convex lens or a Fresnel lens having a positive optical power.

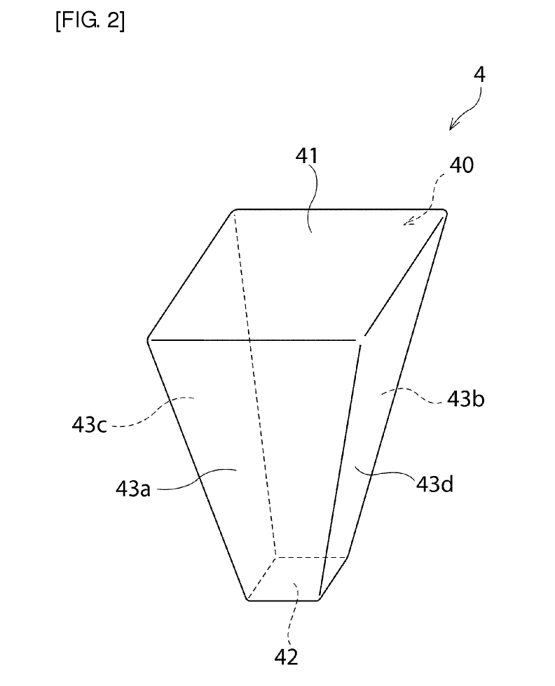

The optical element 4 is disposed between the light collecting member 3 and the solar cell 5. Light collected by the light collecting member 3 enters the optical element 4 through an end surface 41 (see FIG. 2) of the optical element 4. The optical element 4 homogenizes light collected by the light collecting member 3 and guides the light to an acceptance surface 50 of the solar cell 5. Specifically, light having entered the optical element 4 is reflected at the side surfaces 43a to 43d of the optical element 4 to thereby propagate through the optical element 4 while being homogenized. Then, light having propagated through the optical element 4 is emitted as homogenized flat light through an end surface 42 of the optical element 4 toward the acceptance surface 50.

The solar cell 5 is disposed on the end surface 42 of the optical element 4 with the acceptance surface 50 facing the end surface 42. Light emitted through the end surface 42 of the optical element 4 enters the solar cell 5. Then, in the solar cell 5, optical energy is converted into electrical energy.

No particular limitation is placed on the type of the solar cell 5. The solar cell 5 can be formed of, for example, a single-crystal silicon solar cell, a polycrystalline silicon solar cell, a thin-film solar cell, an amorphous silicon solar cell, a dye-sensitized solar cell or an organic semiconductor solar cell.

(Optical Element)

FIG. 2 is a schematic perspective view of the optical element according to this embodiment. Next, a description will be given of a specific structure of the optical element 4 with reference to FIG. 2.

The optical element 4 has a shape tapering from the side adjacent the light collecting member 3 to the side adjacent the solar cell 5. The surface 40 of the optical element 4 includes: two end surfaces 41, 42 constituting the light entrance and exit surfaces; and side surfaces 43a to 43d constituting light-reflecting surfaces. The end surfaces 41, 42 are opposite to each other. The side surfaces 43a to 43d connect the end surfaces 41, 42. The shape of the optical element 4 may be conical or pyramidal. The shape of the end surfaces 41, 42 may be flat or curved. The corners and edges of the optical element 4 may be roundly chamfered, in which case breakage of the optical element 4 due to external shock can be reduced.

The glass forming the optical element 4 contains, in % by mass, 30 to 80% SiO₂, 0 to 40% B₂O₃, 0 to 30% Al₂O₃, not less than 0.1% Li₂O, and 0.1 to 10% ZrO₂. A detailed description will be given below of the reasons why the content of each component is specified as above. Unless otherwise stated, “%” as used hereinafter means “% by mass”.

SiO₂ is a component for forming the glass network and has the effect of reducing devitrification and the effect of increasing weather resistance. This component also has the effect of increasing the Abbe's number. The SiO₂ content is preferably 30 to 80%, more preferably 40 to 75%, still more preferably 45 to 70%, even more preferably 45 to 65%, and particularly preferably 45 to 60%. If the SiO₂ content is too large, the softening point tends to be high and the refractive index tends to decrease. On the other hand, if the SiO₂ content is too small, the glass is likely to be unstable to impair the resistance to devitrification or a phase separation is likely to occur to decrease the weather resistance, such as acid resistance and water resistance. In addition, the coefficient of thermal expansion may increase to decrease the thermal shock resistance.

B₂O₃ is also a component for forming the glass network and has the effect of reducing devitrification and the effect of increasing weather resistance. The B₂O₃ content is preferably 0 to 40%, more preferably 2.5 to 30%, and particularly preferably 5 to 20%. If the B₂O₃ content is too large, the weather resistance tends to decrease and the refractive index tends to decrease.

Al₂O₃ is also a component for forming the glass network and has the effect of reducing devitrification and the effect of increasing weather resistance. The Al₂O₃ content is preferably 0 to 30%, more preferably 2.5 to 25%, and particularly preferably 5 to 20%. If the Al₂O₃ content is too large, the refractive index tends to decrease and the weather resistance tends to decrease.

Li₂O is a component which acts as a flux and has a large effect of decreasing the softening point. The Li₂O content is preferably not less than 0.1%, more preferably not less than 1%, and particularly preferably not less than 2%. If the Li₂O content is too small, the above effect is difficult to achieve. If the Li₂O content is too large, the weather resistance, such as acid resistance and water resistance, tends to decrease. In addition, the coefficient of thermal expansion may increase to decrease the thermal shock resistance. Therefore, the Li₂O content is preferably 20% or less and particularly preferably 15% or less.

ZrO₂ is a component having the effect of dramatically increasing the weather resistance, such as acid resistance and water resistance. The ZrO₂ content is preferably not less than 0.1% and particularly preferably not less than 1%. If the ZrO₂ content is too small, the above effect is difficult to achieve. No particular limitation is placed on the upper limit of the ZrO₂ content. However, if the ZrO₂ content is too large, the viscosity will be high and thus the glass is likely to devitrify. Therefore, the ZrO₂ content is preferably not more than 15%, more preferably not more than 10%, and particularly preferably not more than 5%.

The glass forming the optical element 4 can further contain, in addition to the above components, 0 to 20% CaO, 0 to 20% SrO, 0 to 20% BaO, 0 to 20% MgO, 0 to 20% ZnO, 0 to 20% Na₂O, 0 to 20% K₂O, and 0 to 10% TiO₂.

CaO, SrO, BaO, MgO, and ZnO act as fluxes to exert the effect of decreasing the softening point and decreasing the liquidus temperature. The content of each of these components is preferably 0 to 20% and particularly preferably 0.1 to 10%. If the content of each of these components is too large, the weather resistance, such as acid resistance and water resistance, is likely to decrease.

In order to sufficiently achieve the effect of decreasing the softening point and ensure good weather resistance, the total amount of CaO, SrO, BaO, MgO, and ZnO is preferably appropriately controlled. Specifically, the content of CaO+SrO+BaO+MgO+ZnO is preferably 0.1 to 50%, more preferably 1 to 40%, and particularly preferably 3 to 35%. If the total amount of these components is too small, the effect of decreasing the softening point is difficult to achieve. On the other hand, if the total amount of these components is too large, the weather resistance is likely to decrease.

Na₂O and K₂O act as fluxes to exert the effect of decreasing the softening point and decreasing the liquidus temperature. The content of each of these components is preferably 0 to 20% and particularly preferably 0.1 to 10%. If the content of each of these components is too large, the weather resistance, such as acid resistance and water resistance, is likely to decrease. In addition, the coefficient of thermal expansion may increase to decrease the thermal shock resistance.

In order to achieve the effect of sufficiently decreasing the softening point and ensure good weather resistance and good thermal shock resistance, the total amount of Li₂O, Na₂O, and K₂O as alkali metal oxide components is preferably appropriately controlled. Specifically, the content of Li₂O+Na₂O+K₂O is preferably 0.1 to 30%, more preferably 1 to 25%, and particularly preferably 3 to 20%. If the total amount of these components is too small, the effect of decreasing the softening point is difficult to achieve. On the other hand, if the total amount of these components is too large, the weather resistance is likely to decrease and the coefficient of thermal expansion is likely to increase to decrease the thermal shock resistance.

TiO₂ acts as a flux to decrease the softening point and has the effect of reducing coloration due to ultraviolet rays and the effect of increasing the weather resistance, such as acid resistance and water resistance. The TiO₂ content is preferably 0 to 10% and particularly preferably 0.1 to 5%. If the TiO₂ content is too large, the transmittances in the ultraviolet region in the transmittance curve will shift to the longer wavelength side to cause the glass to be easily colored and the refractive index tends to be high.

The total amount of Bi₂O₃, La₂O₃, Gd₂O₅, Ta₂O₅, TiO₂, Nb₂O₅, and WO₃ may be appropriately controlled, in which case the coloration due to ultraviolet rays can be effectively reduced. Specifically, the content of Bi₂O₃+La₂O₃+Gd₂O₃+Ta₂O₃+TiO₂+Nb₂O₃+WO₃ is preferably 0 to 20%, more preferably 0 to 10%, still more preferably 0.1 to 8%, and particularly preferably 1 to 5%. If the total amount of these components is too large, the transmittance in the visible region may decrease.

To obtain a glass having a low viscosity and excellent weather resistance, the total amount and ratio of the following components are preferably controlled as described below.

The content of SiO₂+Al₂O₃+ZrO₂ is preferably 35 to 80% and particularly preferably 37 to 75%. If the total amount of these components is too large, the viscosity is likely to be high. On the other hand, if the total amount of them is too small, the weather resistance tends to be poor.

The ratio of (SiO₂+Al₂O₃)/ZrO₂ is, in mass ratio, preferably not more than 700 and particularly preferably not more than 650. If this ratio is too high, the weather resistance tends to be poor.

The content of BaO+ZnO is preferably 1.5 to 40% and particularly preferably 2 to 30%. If the total amount of these components is too small, the viscosity tends to be high. On the other hand, if the total amount of them is too large, the weather resistance tends to be poor.

The ratio of (SiO₂+Al₂O₃)/Li₂O is, in mass ratio, preferably not more than 700 and particularly preferably not more than 600. If this ratio is too high, the viscosity tends to be high.

The ratio of (Na₂O+K₂O)/Li_{z}° is, in mass ratio, preferably 0.1 to 100 and particularly preferably 0.2 to 50. If this ratio is too small, the coefficient of thermal expansion may increase to decrease the thermal shock resistance. In addition, the viscosity tends to be high. On the other hand, if the above ratio is too high, the weather resistance tends to be poor.

In addition to the above components, the glass forming the optical element 4 can further contain CeO₂+Nd₂O₂+Pr₂O₂+Eu₂O₂+Tb₂O₂+Er₂O₂+Y₂O₂+Yb₂O₅ in a total amount of 0 to 5% by mass.

CeO₂, Pr₂O₃, Nd₂O₃, Eu₂O₃, Tb₂O₃, Er₂O₃, Y₂O₃, and Yb₂O₅ are components which can produce strong light upon irradiation with visible to near-ultraviolet light. The addition of these components can be expected to increase the amount of light applied to the solar cell and thus improve the power generation efficiency. Specifically, the content of CeO₂+Pr₂O₃+Nd₂O₃+Eu₂O₃+Tb₂O₃+Er₂O₃+Y₂O₃+Yb₂O₅ is preferably 0 to 5%, more preferably 0.1 to 3%, and particularly preferably 0.1 to 1%.

It should be avoided on environmental grounds that a lead component (for example, PbO), an arsenic component (As₂O₂), and an fluorine component (for example, F₂) be substantially introduced into the glass. Therefore, the glass forming the optical element 4 is preferably substantially free of these components.

If a large amount of Fe₂O₃ serving as a coloring component is contained in the glass, the transmittance will decrease, which may cause a reduction in power generation efficiency. Therefore, the Fe₂O₃ content is preferably not more than 0.1%, more preferably not more than 0.05%, and particularly preferably not more than 0.01%.

In addition to the above components, Sb₂O₃, SO₃, NO₃, and carbon can be added as a fining agent, an oxidizing agent or a reducing agent in a total amount of not more than 1%.

No particular limitation is placed on the refractive index (nd) of the glass of the present invention but the refractive index is, for example, preferably 1.5 to 1.7 and particularly preferably 1.5 to 1.6. If the refractive index is too low, light will be likely to leak from the side surfaces 43a to 43d of the optical element 4 to the outside. On the other hand, if the refractive index is too high, light will be likely to reflect on the end surface 41 of the optical element 4 and less likely to enter the inside of the optical element 4.

The surface roughness of the surface 40 of the optical element 4 is, in terms of arithmetic surface roughness (Ra) defined in JIS B0601, preferably not more than 200 nm, more preferably not more than 100 nm, still more preferably not more than 50 nm, even more preferably not more than 20 nm, and particularly preferably not more than 10 nm.

In the optical element 4, the average linear coefficient of thermal expansion at 30 to 300° C. is preferably 120×10⁻⁷/° C. or less, more preferably 110×10⁻⁷/° C. or less, and particularly preferably 100×10⁻⁷/° C. or less. If the average linear coefficient of thermal expansion is too high, the glass may be broken by failure to respond to temperature changes during cooling after molding or during outdoor use. Although no particular limitation is placed on the lower limit of the average linear coefficient of thermal expansion, it is on a realistic level not less than 30×10⁷/° C. and particularly not less than 50×10⁻⁷/° C.

In the optical element 4, the temperature corresponding to a viscosity of 10^{2.0} Pa·s is preferably not higher than 1300° C. and particularly preferably not higher than 1200° C. If the temperature corresponding to a viscosity of 10^{2.0} Pa·s is too high, the meltability and moldability will decrease and thus the refractory during melting or the mold during molding will be likely to degrade.

In the optical element 4, the softening point is preferably not higher than 750° C., more preferably not higher than 700° C., and particularly preferably not higher than 650° C. If the softening point is too high, the mold will be likely to degrade during molding.

In the optical element 4, the internal transmittance of the glass with a thickness of 10 mm at a wavelength of 400 nm is preferably not less than 90%, more preferably not less than 92.5%, and particularly preferably not less than 95%. If the internal transmittance is too low, the power generation efficiency of the concentrating photovoltaic power generation apparatus tends to be poor.

Furthermore, the internal transmittance of the glass with a thickness of 10 mm at a wavelength of 300 nm is preferably not more than 40%, more preferably not more than 30%, still more preferably not more than 20%, even more preferably not more than 10%, and particularly preferably 0%. Moreover, the internal transmittance of the glass with a thickness of 10 mm at a wavelength of 315 nm is preferably not more than 60%, more preferably not more than 40%, still more preferably not more than 20%, and particularly preferably 0%. If the internal transmittance at a wavelength of 300 nm or 315 nm is too high, the amount of ultraviolet rays passing through the optical element will be large, resulting in ease of degradation of a resin adhesive used around the optical element.

The following description is an example of a method for producing the optical element 4.

(Method for Producing Optical Element)

The optical element 4 can be obtained by mechanical polishing processing or press molding. Examples of the press molding include direct pressing in which molten glass is poured directly into a mold and then press-molded; and reheat pressing in which a preform of the optical element obtained by vitrification is reheated to soften and then deformed by pressing. Particularly if an optical element having curved top and bottom surfaces or having a complicated shape is desired, press molding is more advantageous than mechanical polishing.

In producing the optical element 4 by press molding, the degradation of the mold can be reduced by the use of a glass having a low softening point or a low viscosity.

If the glass after the press molding is subjected to, for example, flame polishing, the glass can easily achieve a good surface roughness. The edges and corners of the optical element 4 may be roundly chamfered.

In this embodiment, the description has been given of the case where the optical element 4 has a prismoidal shape. However, the present invention is not limited to this structure and no particular limitation is placed on the structure so long as the optical element 4 has a shape allowing light collection to the solar cell. Furthermore, the end surfaces 41, 42 may not be flat and may be convex or concave.

### EXAMPLES

The present invention will be described below in further detail with reference to specific examples. However, the present invention is not at all limited to the following examples. Modifications and variations may be appropriately made therein without changing the gist of the invention.

Tables 1 to 5 show examples of the present invention (Samples Nos. 1 to 32 and 36 to 43) and comparative examples (Samples Nos. 33 to 35).

TABLE 1

| (% by mass) | 1 | 2 | 3 | 4 | 5 | 6 | 7 | 8 | 9 | 10 |
|---|---|---|---|---|---|---|---|---|---|---|
| SiO₂ | 58.7 | 43.9 | 45.7 | 65 | 62.7 | 40.2 | 58.4 | 58.4 | 42.4 | 50.5 |
| Al₂O₃ | 4 | 1 | 2 | 5.7 | 6 | 2 | 4 | 4 | 6 | |
| B₂O₃ | 12.5 | 10 | 20 | 10.2 | 10 | 15 | 12 | 5 | 5 | 15 |
| MgO | 1 | | | | | | 1 | 2 | 5 | |
| CaO | 1 | | 0.9 | | | 10 | 1 | 2 | | |
| SrO | 1 | 10 | | | | 10 | 1 | 2 | 11 | 10 |
| BaO | | 18 | 2 | | | 10 | | | 16 | 10 |
| ZnO | 4.2 | 8 | 9 | 2 | 2 | | 4 | 4 | 9 | |
| Li₂O | 5 | 3.5 | 4 | 4.5 | 4.5 | 0.2 | 9 | 8 | 4.5 | 3 |
| Na₂O | 6 | 3 | 8 | 7 | 7.3 | | | 7 | 0.5 | 3 |
| K₂O | 6 | 2 | 4 | 5 | 5 | 12 | 9 | 7 | | 8 |
| TiO₂ | | | 4 | | | | | | | |
| ZrO₂ | 0.3 | 0.3 | 0.3 | 0.3 | 0.3 | 0.3 | 0.3 | 0.3 | 0.3 | 0.3 |
| P₂O₃ | | | | | 2 | | | | | |
| Y₂O₃ | | | | | | | | | | |
| Sb₂O₃ | 0.3 | 0.3 | 0.1 | 0.3 | 0.2 | 0.3 | 0.3 | 0.3 | 0.3 | 0.2 |
| Si + Al + Zr | 63 | 45.2 | 48 | 71 | 69 | 42.5 | 62.7 | 62.7 | 48.7 | 50.8 |
| (Si + Al)/Zr | 209.0 | 149.7 | 159.0 | 235.7 | 229.0 | 140.7 | 208.0 | 208.0 | 161.3 | 168.3 |
| Ba + Zn | 4.2 | 26 | 11 | 2 | 2 | 10 | 4 | 4 | 25 | 10 |
| (Si + Al)/Li | 12.5 | 12.8 | 11.9 | 15.7 | 15.3 | 211.0 | 6.9 | 7.8 | 10.8 | 16.8 |
| (Na + K)/Li | 2.4 | 1.4 | 3.0 | 2.7 | 2.7 | 60.0 | 1.0 | 1.8 | 0.1 | 3.7 |
| Coefficient of Thermal Expansion | 94 | 92 | 91 | 85 | 86 | 90 | 92 | 119 | 89 | 91 |
| (×10⁻⁷/° C.) | | | | | | | | | | |
| Softening Point (° C.) | 600 | 620 | 575 | 620 | 640 | 730 | 590 | 550 | 630 | 640 |
| Temperature at 10^{2.0} Pa · s (° C.) | 1120 | 1010 | 960 | 1295 | 1290 | 1150 | 1080 | 1080 | 1050 | 1080 |
| Internal Transmittance at 400 nm (%) | 99.7 | 99.6 | 97.5 | 99.5 | 99 | 99.6 | 99.6 | 99.5 | 99.6 | 99.6 |
| Weather Resistance | ◯ | ◯ | ◯ | ◯ | ◯ | ◯ | ◯ | ◯ | ◯ | ◯ |

TABLE 2

| (% by mass) | 11 | 12 | 13 | 14 | 15 | 16 | 17 | 18 | 19 | 20 |
|---|---|---|---|---|---|---|---|---|---|---|
| SiO₂ | 56.7 | 57.7 | 42.2 | 44.3 | 42.8 | 43.7 | 46 | 39.4 | 49 | 49 |
| Al₂O₃ | 1 | | 0.5 | | | | | | 1.5 | 1.5 |
| B₂O₃ | 1 | 1 | 15 | 11.0 | 12 | 22.4 | 12.5 | 18 | 18 | 16.5 |
| MgO | 3 | 5 | 0.5 | | | | | | | |
| CaO | | | 0.5 | 15.0 | | 2.1 | 3.7 | 2 | 1.3 | 1.3 |
| SrO | 5 | 6 | 7 | | 10 | 3.5 | 7 | 5 | 2.4 | 2.4 |
| BaO | 11.5 | 7 | 12 | | 16.5 | 6 | 10 | 7 | 3.6 | 3.6 |
| ZnO | 8 | 6 | 7 | 19.5 | 8 | 5.1 | 10 | 8 | 4.4 | 4.4 |
| Li₂O | 3.5 | 2 | 13 | 4.0 | 4 | 6.2 | 3.4 | 3.7 | 4.1 | 4.3 |
| Na₂O | 2.5 | 3.7 | 0.5 | 2.9 | 2.9 | | 6.1 | | 8.4 | 8.6 |
| K₂O | 6 | 8.3 | 0.5 | 2.0 | 2 | 9.7 | | 11.6 | 3 | 3.1 |
| TiO₂ | 0.5 | 2 | | | | | | | 5 | |
| ZrO₂ | 1 | 1 | 1 | 1.0 | 1 | 1 | 1 | 1 | 1 | 5 |
| P₂O₃ | | | | | 0.5 | | | | | |
| Y₂O₃ | | | | | | | | 4 | | |
| Sb₂O₃ | 0.3 | 0.3 | 0.3 | 0.3 | 0.3 | 0.3 | 0.3 | 0.3 | 0.3 | 0.3 |
| Si + Al + Zr | 58.7 | 58.7 | 43.7 | 45.3 | 43.8 | 44.7 | 47 | 40.4 | 51.5 | 55.5 |
| (Si + Al)/Zr | 57.7 | 57.7 | 42.7 | 44.3 | 42.8 | 43.7 | 46.0 | 39.4 | 50.5 | 10.1 |
| Ba + Zn | 19.5 | 1.3 | 19 | 19.5 | 24.5 | 11.1 | 20 | 15 | 8 | 8 |
| (Si + Al)/Li | 16.5 | 28.9 | 3.3 | 11.1 | 10.7 | 7.0 | 18.5 | 10.6 | 12.3 | 11.7 |
| (Na + K)/Li | 2.4 | 6.0 | 0.1 | 1.2 | 1.2 | 1.6 | 1.6 | 3.1 | 2.8 | 2.7 |
| Coefficient of Thermal Expansion (×10⁻⁷/° C.) | 94 | 93 | 94 | 95 | 94 | 92 | 92 | 93 | 95 | 33 |
| Softening Point (° C.) | 630 | 680 | 660 | 610 | 600 | 590 | 610 | 610 | 599 | 608 |
| Temperature at 10^{2.0} Pa · s (° C.) | 1230 | 1290 | 990 | 960 | 970 | 920 | 990 | 960 | 992 | 1040 |
| Internal Transmittance at 400 nm (%) | 98.7 | 98.3 | 98.5 | 99.4 | 99.2 | 99.5 | 99.5 | 99 | 98 | 99.4 |
| Internal Transmittance at 315 nm (%) | 0.5 | | | | | | | | | |
| Internal Transmittance at 300 nm (%) | 0 | | | | | | | | | |
| Wavelength at Internal Transmittance of 0% (nm) | 314 | | | | | | | | | |
| Weather Resistance | ◯ | ◯ | ◯ | ◯ | ◯ | ◯ | ◯ | ◯ | ◯ | ◯ |

TABLE 3

| (% by mass) | 21 | 22 | 23 | 24 | 25 | 26 | 27 | 28 | 29 | 30 |
|---|---|---|---|---|---|---|---|---|---|---|
| SiO₂ | 45 | 45 | 45.7 | 48.0 | 43.7 | 43.2 | 53.7 | 50 | 36.7 | 50.2 |
| Al₂O₃ | 1.5 | 1.5 | 1.8 | | 2 | 1.5 | 0.5 | 0.5 | 0.5 | 0.5 |
| B₂O₃ | 16 | 16 | 12.6 | 18.0 | 25 | 21 | 6 | 14.5 | 31 | 18.5 |
| MgO | | | | | | | | | | |
| CaO | 1.3 | 1.3 | | 2.0 | | | | 1 | 1 | 1 |
| SrO | 2.4 | 2.4 | 8 | 4.0 | 3 | 0.5 | | | | |
| BaO | 3.6 | 3.6 | 11.8 | 6.0 | 4 | 1 | | | | |
| ZnO | 4.4 | 4.4 | 1.3 | 7.5 | 1 | 8 | 23 | 12 | 10 | 11 |
| Li₂O | 4.1 | 4.1 | 6.7 | 4.0 | 5 | 4.5 | 2.5 | 2.5 | 3.5 | 2 |
| Na₂O | 8.4 | 8.4 | 1.8 | 8.5 | 6 | 5.5 | 5 | 5.5 | 3 | 4.5 |
| K₂O | 3 | 3 | | | 6 | 6.5 | 8 | 8.5 | 11 | 8 |
| TiO₂ | 5 | 5 | 5 | | 2 | 7 | | 5 | 2.5 | 3 |
| ZrO₂ | 5 | 5 | 5 | 1.0 | 2 | 1 | 1 | 0.2 | 0.5 | 1 |
| P₂O₅ | | | | | | | | | | |
| SnO₂ | | | | 1 | | | | | | |
| Sb₂O₃ | 0.3 | 0.3 | 0.3 | | 0.3 | 0.3 | 0.3 | 0.3 | 0.3 | 0.3 |
| Si + Al + Zr | 51.5 | 51.5 | 52.5 | 49 | 47.7 | 45.7 | 55.2 | 50.7 | 37.7 | 51.7 |
| (Si + Al)/Zr | 9.3 | 9.3 | 9.5 | 48.0 | 22.9 | 44.7 | 54.2 | 252.5 | 74.4 | 50.7 |
| Ba + Zn | 8 | 8 | 13.1 | 13.5 | 5 | 9 | 23 | 12 | 10 | 11 |
| (Si + Al)/Li | 11.3 | 11.3 | 7.1 | 12.0 | 9.1 | 9.9 | 21.7 | 20.2 | 10.6 | 25.4 |
| (Na + K)/Li | 2.8 | 2.8 | 0.3 | 2.1 | 2.4 | 2.7 | 5.2 | 5.6 | 4.0 | 6.3 |
| Coefficient of Thermal Expansion (×10⁻⁷/° C.) | 95 | 93 | 94 | 90 | 96 | 94 | 92 | 92 | 91 | 80 |
| Softening Point (° C.) | 603 | 680 | 660 | 610 | 590 | 575 | 610 | 600 | 570 | 620 |
| Temperature at 10^{2.0} Pa · s (° C.) | 990 | 1290 | 990 | 990 | 930 | 930 | 1180 | 1040 | 890 | 1080 |
| Internal Transmittance at 400 nm (%) | 98.1 | 98 | 98.1 | 90.8 | 90.4 | 97.5 | 99.5 | 98.1 | 98.3 | 98.4 |
| Internal Transmittance at 315 nm (%) | | | | 72 | 0 | 0 | 74.4 | 0 | 0 | 0 |
| Internal Transmittance at 300 nm (%) | | | | 28 | 0 | 0 | 31 | 0 | 0 | 0 |
| Wavelength at Internal Transmittanse of 0% (nm) | | | | 291 | 322 | 327 | 289 | 325 | 324 | 323 |
| Weather Resistance | ◯ | ◯ | ◯ | ◯ | ◯ | ◯ | ◯ | ◯ | ◯ | ◯ |

TABLE 4

| (% by mass) | 31 | 32 | 33 | 34 | 35 | 36 | 37 | 38 | 39 |
|---|---|---|---|---|---|---|---|---|---|
| SiO₂ | 52.2 | 70 | 68.2 | 47 | 59.5 | 44.7 | 44.7 | 44.5 | 47.3 |
| Al₂O₃ | 4 | 9 | 5 | 1.5 | 5.5 | 0.5 | 0.5 | 0.5 | |
| B₂O₃ | 20 | | 11 | 12.3 | | 14.1 | 13.8 | 13.7 | 13.6 |
| MgO | | | | | | | | | |
| CaO | | | 3 | 1.3 | 1.5 | 1 | 1 | 1 | 1 |
| SrO | | | | 2.4 | | | | | |
| BaO | | | | 3.6 | | | | | |
| ZnO | 5 | 2 | 1 | 4.4 | 2 | 12.2 | 12 | 11.9 | 11.8 |
| Li₂O | 7 | 0.7 | | 41 | 1 | 2.4 | 2.4 | 2.4 | 2.3 |
| Na₂O | 9.5 | 9 | 11 | 8.4 | 27 | 5.4 | 5.3 | 5.3 | 5.2 |
| K₂O | | 8 | | 3 | 3 | 8.3 | 8.2 | 8.1 | 8.1 |
| TiO₂ | 1.5 | | | 12 | | 7.3 | 4.8 | 4.8 | |
| ZrO₂ | 0.5 | 1 | 0.5 | | | 3.7 | 3.4 | 3.9 | 3.6 |
| Nb₂O₅ | | | | | | | | 3.6 | 6.7 |
| WO₃ | | | | | | | 3.6 | | |
| P₂O₅ | | | | | | | | | |
| SnO₂ | | | | | | | | | |
| Sb₂O₃ | 0.3 | 0.3 | 0.3 | | 0.5 | 0.4 | 0.3 | 0.3 | 0.4 |
| Si + Al + Zr | 56.7 | 80 | 73.7 | 48.5 | 65 | 48.9 | 48.6 | 48.9 | 50.9 |
| (Si + Al)/Zr | 112.4 | 79.0 | — | — | — | 12.2 | 13.3 | 11.5 | 13.1 |
| Ba + Zn | 5 | 2 | 1 | 8 | 2 | 12.2 | 12 | 11.9 | 11.8 |
| (Si + Al)/Li | 8.0 | 112.8 | — | 11.8 | 65.0 | 18.8 | 18.8 | 18.8 | 20.6 |
| (Na + K)/Li | 1.4 | 24.3 | — | 2.8 | 30.0 | 5.7 | 5.6 | 5.6 | 5.8 |
| Coefficient of Thermal Expansion (×10⁻⁷/° C.) | 94 | 97 | 65 | 100 | 129 | 87 | 86 | 86 | 85 |
| Softening Point (° C.) | 580.0 | 730.0 | 765.0 | 570.0 | | 594.0 | 598.0 | 599.0 | 604.0 |
| Temperature at 10^{2.0} Pa · s (° C.) | 960 | 1190 | 1300< | | | 1010 | 1025 | 1020 | 1000 |
| Internal Transmittance at 400 nm (%) | 98.5 | 99.5 | 99.6 | 86 | 99.5 | 97 | 98 | 97.6 | 98.9 |
| Internal Transmittance at 315 nm (%) | | | 80.1 | | | 0 | 0 | 0 | 20 |
| Internal Transmittance at 300 nm (%) | | | 45 | | | 0 | 0 | 0 | 0 |
| Wavelength at Internal Trarsmittance of 0% (nm) | | | 276 | | | 335 | 332 | 327 | 300 |
| Weather Resistance | ◯ | ◯ | ◯ | X | X | ◯ | ◯ | ◯ | ◯ |

TABLE 5

| (% by mass) | 40 | 41 | 42 | 43 |
|---|---|---|---|---|
| SiO₂ | 44.7 | 44.5 | 43.2 | 40.6 |
| Al₂O₃ | 0.5 | 0.5 | 0.5 | 0.4 |
| B₂O₃ | 13.8 | 13.7 | 13.3 | 12.5 |
| MgO | | | | |
| CaO | 1.0 | 1.0 | 1.0 | 0.9 |
| SrO | | | | |
| BaO | | | | |
| ZnO | 12.0 | 11.9 | 11.6 | 10.8 |
| Li₂O | 2.4 | 2.4 | 2.3 | 2.1 |
| Na₂O | 5.3 | 5.3 | 5.1 | 4.8 |
| K₂O | 8.2 | 8.1 | 7.9 | 7.4 |
| TiO₂ | 4.8 | 4.8 | 4.6 | 4.4 |
| ZrO₂ | 3.6 | 3.6 | 3.5 | 3.3 |
| Bi₂O₃ | | | 6.6 | 12.4 |
| Nb₂O₅ | | 3.9 | | |
| WO₃ | 3.4 | | | |
| P₂O₅ | | | | |
| SnO₂ | | | | |
| Sb₂O₃ | 0.3 | 0.3 | 0.4 | 0.4 |
| Si + Al + Zr | 48.8 | 48.6 | 47.2 | 44.3 |
| (Si + Al)/Zr | 12.6 | 12.5 | 12.5 | 12.4 |
| Ba + Zn | 12 | 11.9 | 11.6 | 10.8 |
| (Si + Al)/Li | 18.8 | 18.8 | 19.0 | 19.5 |
| (Na + K)/Li | 5.6 | 5.6 | 5.7 | 5.8 |
| Coefficient of Thermal Expansion (×10⁻⁷/° C.) | 86.6 | 86.8 | 88 | 90 |
| Softening Point (° C.) | 608.0 | 608.0 | 595.0 | 579.0 |
| Temperature at 10^{2.0} Pa · s (° C.) | 1070 | 1070 | 1040 | 1010 |
| Internal Transmittance at 400 nm (%) | 98.9 | 90.3 | 97 | 93 |
| Internal Transmittance at 315 nm (%) | 0 | 0 | 0 | 0 |
| Internal Transmittance at 300 nm (%) | 0 | 0 | 0 | 0 |
| Wavelength at Internal Transmittance of 0% (nm) | 338 | 336 | 341 | 349 |
| Weather Resistance | ◯ | ◯ | ◯ | ◯ |

The individual samples were prepared in the following manner.

First, each set of glass raw materials were mixed together to give a corresponding composition shown in the above tables and melted at 1000 to 1400° C. for four hours using a platinum crucible. After the melting, the glass melt was allowed to flow on a carbon plate and annealed and then glass samples suitable for the respective measurements were produced.

The resultant samples were measured in terms of coefficient of thermal expansion, softening point, temperature corresponding to a viscosity of 10^{2.0} Pa·s, and internal transmittance. Furthermore, the samples were evaluated for weather resistance. The results are shown in Tables 1 to 5.

As seen from the tables, Samples Nos. 1 to 32 and 36 to 43, all of which are examples of the present invention, exhibited excellent characteristics: a coefficient of thermal expansion of not more than 119×10⁻⁷/° C., a softening point of not more than 730°, a temperature of not more than 1295° C. corresponding to a viscosity of 10^{2.0} Pa·s, and an internal transmittance of not less than 90.3% at a wavelength of 400 nm with a thickness of 10 mm. In addition, these samples exhibited good resistance to devitrification.

On the other hand, Sample No. 33, which is one of the comparative examples, exhibited a softening point as high as 765° C. and was therefore unsuitable for reheat pressing. In addition, the temperature corresponding to a viscosity of 10^{2.0} Pa·s was above 1300° C. and was therefore unsuitable for direct pressing. Sample No. 34 was poor in weather resistance and can be therefore considered to be difficult to use outdoors for long periods. In addition, the internal transmittance at a wavelength of 400 nm with a thickness of 10 mm was as low as 86% and can be therefore considered to be poor in power generation efficiency of a solar cell. Sample No. 35 exhibited a coefficient of thermal expansion as high as 129×10⁻⁷/° C. and can be therefore considered to be likely to be broken during press molding or during outdoor use. In addition, this sample was poor in weather resistance.

The above characteristics were measured and evaluated in the following manners.

The coefficient of thermal expansion was measured with a dilatometer.

The softening point was measured by the fiber elongation method based on ASTM 338-93.

The temperature corresponding to a viscosity of 10^{2.0} Pa·s was measured by the platinum ball pulling-up method.

In terms of the internal transmittance, each of an optically polished sample with a thickness of 5 mm±0.1 mm and an optically polished sample with a thickness of 10 mm±0.1 mm was first measured in terms of transmittance (inclusive of surface reflectance loss) in a wavelength range of 200 to 800 nm at 0.5 nm intervals using a spectro-photometer (UV-3100 manufactured by Shimadzu Corporation). Then, for each sample, the internal transmittances at wavelengths of 400 nm, 315 nm, and 300 nm were calculated from the measured values. Furthermore, the wavelength at which the sample exhibited an internal transmittance of 0% was read.

In terms of the weather resistance, each sample was allowed to stand in a thermo-hygrostat at a temperature of 85° C. and a humidity of 85% for 2000 hours and then the sample surface was observed in a microscope. Samples in which neither clouding nor precipitate was observed on the surface were evaluated to be good (“∘”) and samples in which clouding or surface precipitates were observed on the surface were evaluated to be no good (“x”).

### REFERENCE SIGNS LIST

1 . . . concentrating photovoltaic power generation apparatus
2 . . . collecting optical system
3 . . . light collecting member
4 . . . optical element
40 . . . surface
41, 42 . . . end surface
43a, 43b, 43c, 43d . . . side surface
5 . . . solar cell
50 . . . acceptance surface

1. A glass used in an optical element for a concentrating photovoltaic power generation apparatus, the glass containing, in % by mass, 30 to 80% SiO₂, 0 to 40% B₂O₃, 0 to 20% Al₂O₃, not less than 0.1% Li₂O, and not less than 0.1% ZrO₂.

2. The glass according to claim 1, further containing, in % by mass, 0 to 20% CaO, 0 to 20% SrO, 0 to 20% BaO, 0 to 20% MgO, 0 to 20% ZnO, 0 to 20% Na₂O, 0 to 20% K₂O, and 0 to 10% TiO₂.

3. The glass according to claim 1, further containing, in % by mass, 0 to 20% Bi₂O₃+La₂O₃+Gd₂O₅+Ta₂O₅+TiO₂+Nb₂O₅+WO₃.

4. The glass according to claim 1, further containing, in % by mass, 0 to 5% CeO₂+Pr₂O₃+Nd₂O₃+Eu₂O₃+Tb₂O₃+Er₂O₃+Y₂O₃+Yb₂O₅.

5. The glass according to claim 1, containing not more than 0.1% Fe₂O₃.

6. The glass according to claim 1, the glass being substantially free of lead component, arsenic component and fluorine component.

7. The glass according to claim 1, having an average linear coefficient of thermal expansion of 120×10⁻⁷/° C. or less at 30 to 300° C.

8. The glass according to claim 1, wherein the temperature corresponding to a viscosity of 10^{2.0} Pa·s is 1300° C. or less.

9. The glass according to claim 1, having a softening point of 750° C. or less.

10. The glass according to claim 1, wherein the glass with a thickness of 10 mm has an internal transmittance of not less than 90% at a wavelength of 400 nm.

11. The glass according to claim 1, where the glass with a thickness of 10 mm has an internal transmittance of not more than 40% at a wavelength of 300 nm.

12. An optical element for a concentrating photovoltaic power generation apparatus, the optical element being made of the glass according to claim 1.

13. A concentrating photovoltaic power generation apparatus comprising a solar cell and a collecting optical system configured to collect light to the solar cell, the collecting optical system including the optical element according to claim 12.
